(19) United States
(12) Patent Application Publication
(10) Pub. No.: US 2017/0207118 A1
(43) Pub. Date: Jul. 20, 2017

(54) SELF-ALIGNED SOURCE/DRAIN CONTACT IN REPLACEMENT METAL GATE PROCESS

(71) Applicant: GLOBALFOUNDRIES Inc., Grand Cayman (KY)

(72) Inventors: Wen Pin PENG, Clifton Park, NY (US); Min-hwa CHI, San Jose, CA (US); Yue HU, Mechanicville, NY (US)

(73) Assignee: GLOBALFOUNDRIES Inc., Grand Cayman (KY)

(21) Appl. No.: 14/995,838

(22) Filed: Jan. 14, 2016

(51) Int. Cl. H01L 21/768; H01L 29/08; H01L 23/535; H01L 29/06; H01L 29/66; H01L 21/28

(52) U.S. Cl. CPC H01L 21/76829; H01L 29/66545; H01L 21/28123; H01L 21/76805; H01L 21/76897; H01L 23/535; H01L 29/0653; H01L 29/0847

(57) ABSTRACT

A starting semiconductor structure for a RMG process includes a semiconductor substrate, transistors in process having dummy gates and electrically isolated by isolation regions. The dummy gates are replaced with metal gates and gate caps, the structure being planarized after replacing the gate. A cap layer is formed over the planarized structure, and trenches are formed through the cap to expose source and drain regions of the transistors, which allows for self-aligned source and drain contacts. Semiconductor structures including the source and drain trenches for self-aligned source/drain contacts are also presented.

### BACKGROUND OF THE INVENTION

Technical Field

The present invention generally relates to semiconductor fabrication. More particularly, the present invention relates to self-aligned source/drain contacts in a replacement metal gate (RMG) process.

Background Information

In a RMG process with ever smaller transistor size, self-aligned source/drain contacts have been employed. However, there has been a trade-off between the use of a contact etch stop layer (CESL) and capping of the replacement metal gate.

Thus, a need exists for improved self-aligned source/drain contacts without the trade-off in a RMG process.

### SUMMARY OF THE INVENTION

The shortcomings of the prior art are overcome and additional advantages are provided through the provision, in one aspect, of a method of fabricating a self-aligned contact in a replacement metal gate (RMG) process. The method includes providing a starting semiconductor structure, the starting semiconductor structure including a semiconductor substrate, a plurality of transistors in process having dummy gates and electrically isolated by isolation regions. The method further includes replacing the dummy gates with metal gates and gate caps, planarizing the structure after the replacing, forming a cap over the planarized structure, and forming trenches through the cap to expose source regions and drain regions of the transistors, allowing for self-aligned source and drain contacts.

In accordance with another aspect, a semiconductor structure is provided. The semiconductor structure includes a semiconductor substrate, a plurality of transistors electrically isolated by isolation regions, each transistor having a metal gate with gate cap and spacers, a source and a drain. The structure further includes one or more protective layers on the isolation regions and along adjacent source and drain sidewalls, and a blanket cap layer over the semiconductor structure with trenches therein exposing the sources and drains.

In accordance with a third aspect, a semiconductor structure is provided. The semiconductor structure includes a semiconductor substrate, a plurality of transistors electrically isolated by isolation regions, each transistor having a dummy gate with gate cap and spacers, a source and a drain. The structure further includes a protective layer only on vertical sidewalls of the sources, drains and spacers.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a cross-sectional view of one example of a starting semiconductor structure, the starting structure including a semiconductor substrate with transistors in fabrication, electrically isolated from each other by isolation regions, each transistor including a dummy gate with a gate cap and spacers, a source and a drain, the starting structure covered by a conformal contact etch stop layer (CESL), in accordance with one or more aspects of the present invention.

FIG. 2 depicts one example of the starting semiconductor structure of FIG. 1 after removing the horizontal portions of CESL and covering the structure with a blanket conformal dielectric layer, in accordance with one or more aspects of the present invention.

FIG. 3 depicts one example of the structure of FIG. 2 after replacing the dummy gates with metal gates having a gate cap and spacers, forming a blanket conformal protective layer, planarizing down to the gate caps, covering the planarized structure with a blanket cap precursor layer and forming a cap layer on the cap precursor layer, in accordance with one or more aspects of the present invention.

FIG. 4 depicts one example of the structure of FIG. 3 after forming trenches through the cap layers and exposing the sources and drains, in accordance with one or more aspects of the present invention.

FIG. 5 depicts one example of a starting semiconductor structure similar to that of FIG. 1, except there no CESL, in accordance with one or more aspects of the present invention.

FIG. 6 depicts one example of the starting structure of FIG. 5 after replacing the dummy gates with metal gates having a gate cap and spacers, planarizing down to the gate caps, covering the planarized structure with a blanket cap precursor layer and forming a cap layer on the cap precursor layer, in accordance with one or more aspects of the present invention.

FIG. 7 depicts one example of the structure of FIG. 6 after forming a low-k dielectric layer on the isolation regions and along adjacent source and drain sidewalls, and forming trenches through the cap layers and exposing the sources and drains, in accordance with one or more aspects of the present invention.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

As used herein, unless otherwise specified, the term “about” used with a value, such as measurement, size, etc., means a possible variation of plus or minus five percent of the value. Also, unless otherwise specified, a given aspect of semiconductor fabrication described herein may be accomplished using conventional processes and techniques, where part of a method, and may include conventional materials appropriate for the circumstances, where a semiconductor structure is described.

Reference is made below to the drawings, which are not drawn to scale for ease of understanding, wherein the same reference numbers are used throughout different figures to designate the same or similar components.

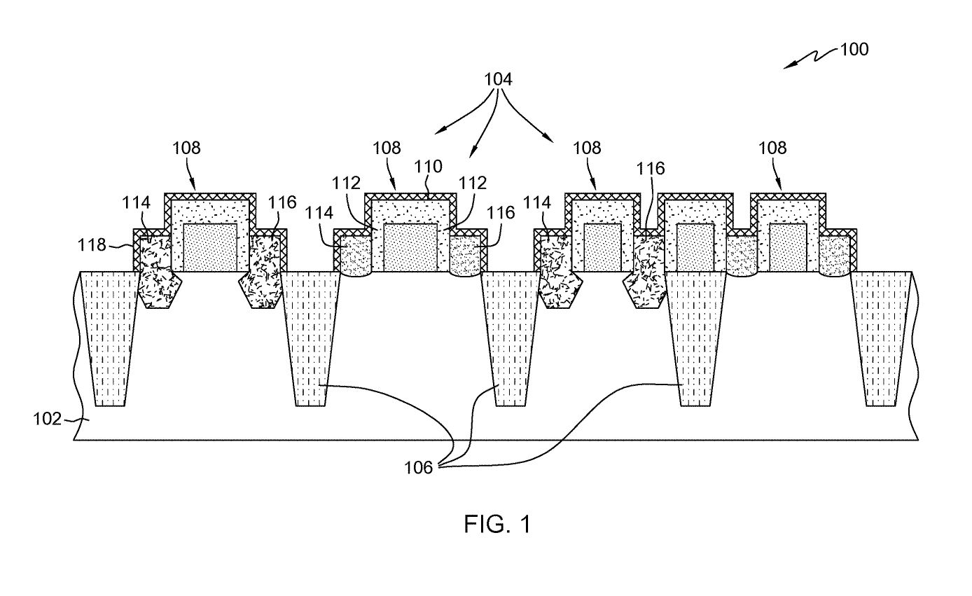

FIG. 1 is a cross-sectional view of one example of a starting semiconductor structure 100, the starting structure including a semiconductor substrate 102 with transistors 104 in fabrication, electrically isolated from each other by isolation regions 106, each transistor including a dummy gate 108 with gate cap 110 (hard mask) and spacers 112, a source 114 and a drain 116, the starting structure covered by a conformal contact etch stop layer 118 (CESL, typically Si-nitride)), in accordance with one or more aspects of the present invention.

The starting structure may be conventionally fabricated, for example, using known processes and techniques. Further, unless noted otherwise, conventional processes and techniques may be used to achieve individual steps of the fabrication process of the present invention. However, although only a portion is shown for simplicity, it will be understood that, in practice, many such structures are typically included on the same bulk substrate.

In one example, substrate 102 may include any silicon-containing substrate including, but not limited to, silicon (Si), single crystal silicon, polycrystalline Si, amorphous Si, silicon-on-nothing (SON), silicon-on-insulator (SOI) or silicon-on-replacement insulator (SRI) or silicon germanium substrates and the like. Substrate 102 may in addition or instead include various isolations, dopings and/or device features. The substrate may include other suitable elementary semiconductors, such as, for example, germanium (Ge) in crystal, a compound semiconductor, such as silicon carbide (SiC), gallium arsenide (GaAs), gallium phosphide (GaP), indium phosphide (InP), indium arsenide (InAs), and/or indium antimonide (InSb) or combinations thereof; an alloy semiconductor including GaAsP, AlInAs, GaInAs, GaInP, or GaInAsP or combinations thereof.

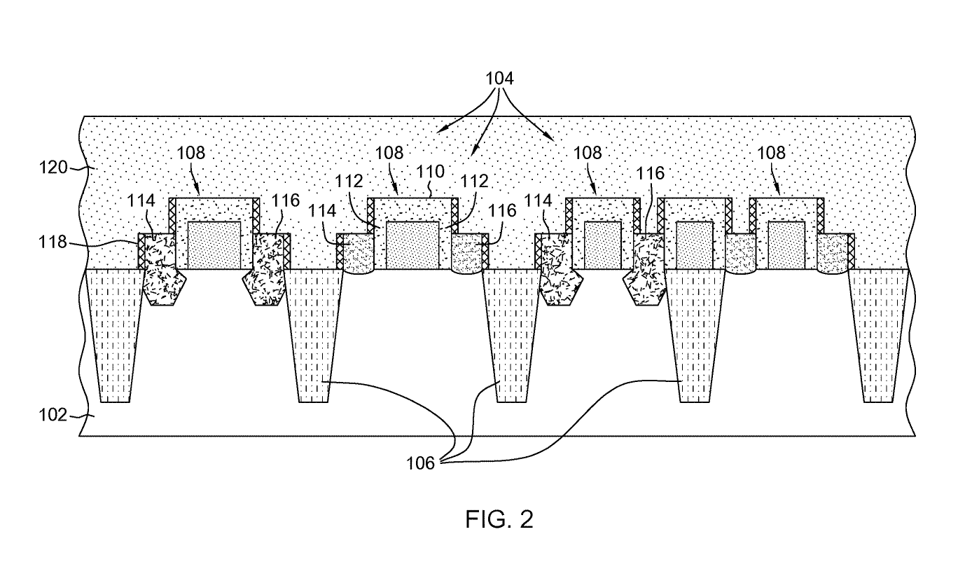

FIG. 2 depicts one example of the starting semiconductor structure of FIG. 1 after removing the horizontal portions of CESL 118, for example, by anisotropic plasma etching, and covering the structure with a blanket conformal dielectric layer 120, in accordance with one or more aspects of the present invention.

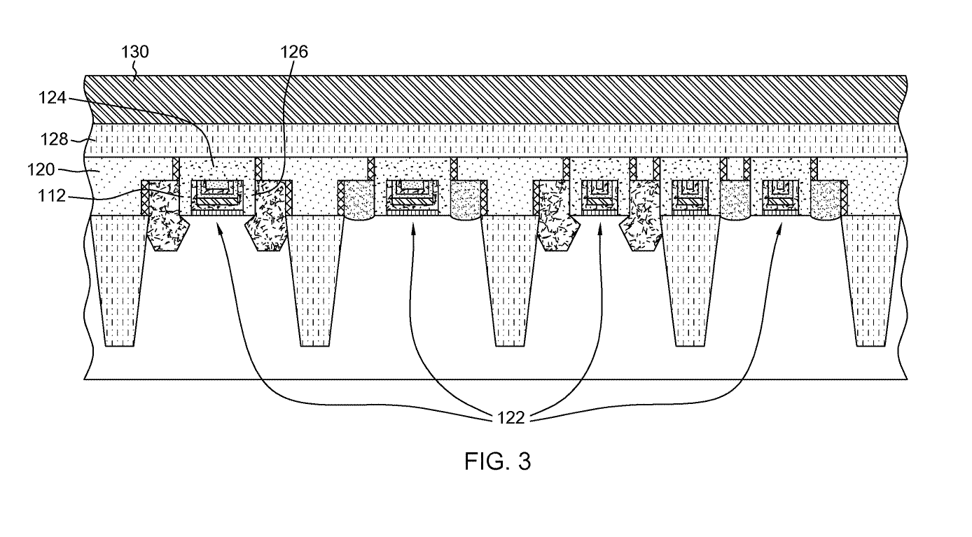

FIG. 3 depicts one example of the structure of FIG. 2 after replacing the dummy gates (108, FIG. 1) with metal gate stacks 122, each having a gate cap 124 on top for self-aligned contact and spacers 112 from FIG. 2. Replacing the dummy gates may be accomplished by, for example, planarizing layer 120 down to the gate caps, etching the gate cap material 110 and the dummy gate material (e.g., poly-Si), then formation of the gate stack layers (e.g., one or more high-k dielectrics, work function layer(s), and electrode metal layer(s), followed by CMP), the covering of the structure with blanket cap layer 128 planarized (e.g., by CMP) and formation of a second cap layer 130, in accordance with one or more aspects of the present invention.

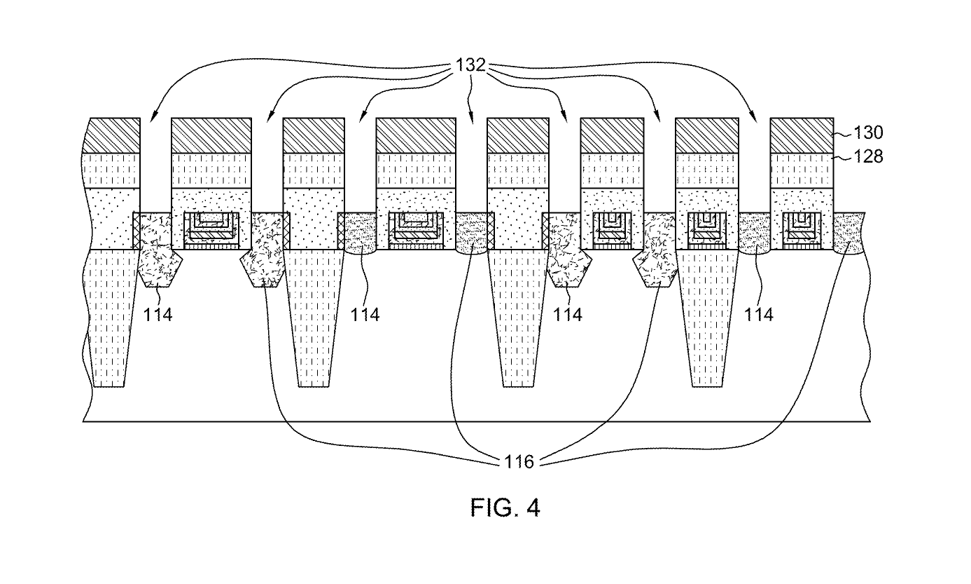

FIG. 4 depicts one example of the structure of FIG. 3 after forming trenches 132 for contacts to the sources and drains by a litho/masking step and etching through cap layers 128 and 130 and exposing the sources 114 and drains 116, in accordance with one or more aspects of the present invention. Note that the trench mask is aligned to the gate structures with misalignment or overlay, thus, the etching of trench 132 through cap layers 128 and 130 is selective to the material of the spacer 126 and gate cap 124. In this way, the trench contact is self-aligned to the gate structure.

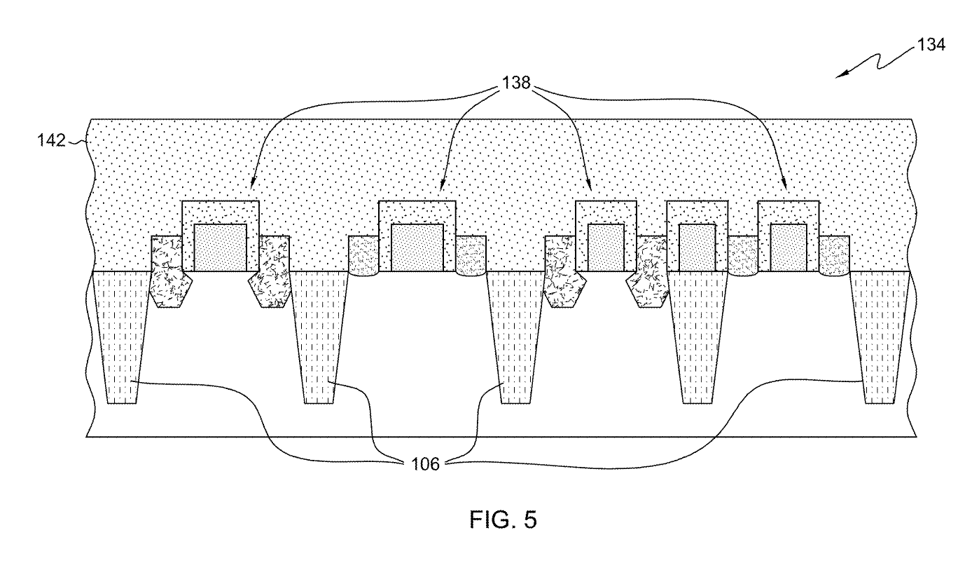

FIG. 5 depicts one example of a starting semiconductor structure 134 similar to that of FIG. 1, except there is no CESL. The structure is covered with a blanket conformal dielectric layer 142, in accordance with one or more aspects of the present invention.

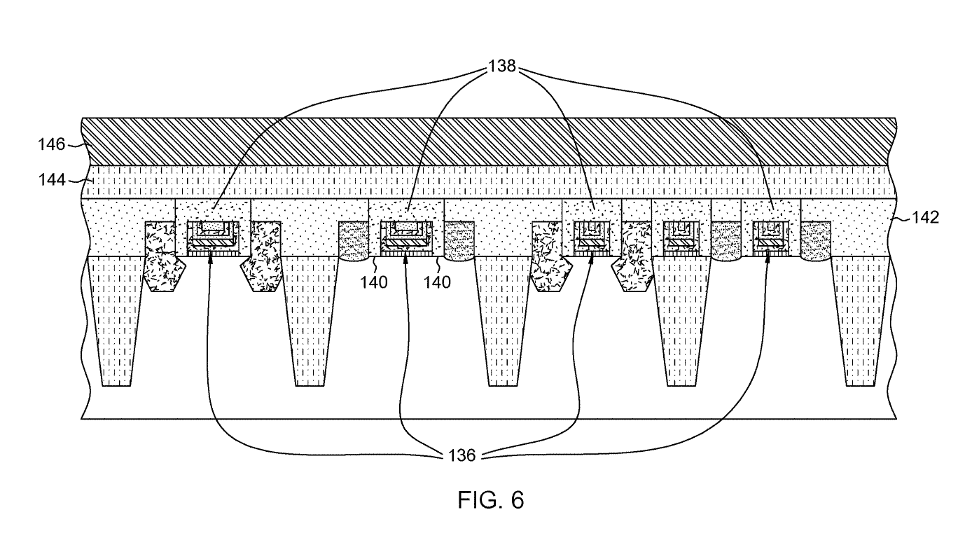

FIG. 6 depicts one example of the starting structure (134, FIG. 5) after replacing the dummy gates (108, FIG. 1) with metal gate stacks 136 having a gate cap 138 and spacers 140, planarizing down to the gate caps, and covering the planarized structure with blanket cap layers 144 and 146, in accordance with one or more aspects of the present invention.

In one example, forming the cap layer(s) (e.g., inter-layer dielectric, ILD) include, for example, forming a first blanket cap layer over the metal gate stacks, and forming a second blanket cap layer over the first blanket cap layer. The materials of the capping layers (e.g., SiOC, or low-k with Carbon in Si-oxide) are etch selective with respect to the spacer and the gate cap materials (e.g., Si-nitride), so that the trench contact formation is “self-aligned” with respect to the gate stack. The capping ILD also serve the same characteristics as (CESL) by suppressing moisture into the underneath gate structure and transistor for good reliability.

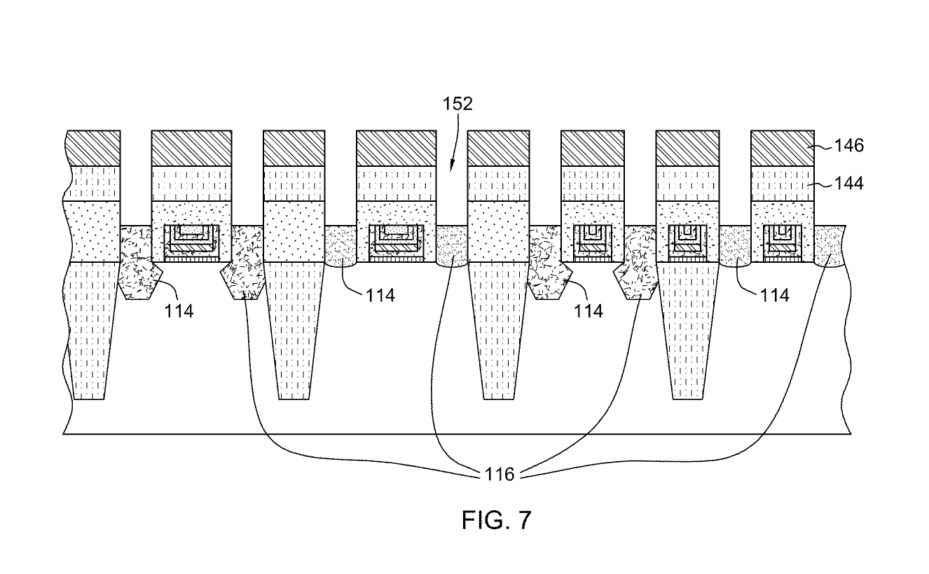

FIG. 7 depicts one example of the structure of FIG. 6 after forming a low-k (dielectric constant k<3.9) dielectric layer 148 on the isolation regions and along adjacent source and drain sidewalls 150, and forming trenches 152, for example, by a litho/masking process, etching through cap layers 144 and 146 and exposing the sources 114 and drains 116, in accordance with one or more aspects of the present invention. Note that the trench mask (of the litho/masking process) is aligned to the gate structures with misalignment or overlay, thus, the etching of trench 152 through cap layer 144 and 146 is selective to the material of the spacer 140 and gate cap 138. In this way, a trench contact in trenches 152 may be self-aligned to the gate structure.

In a first aspect, disclosed above is a method. The method includes providing a starting semiconductor structure, the starting semiconductor structure including a semiconductor substrate, transistors in process having dummy gates and electrically isolated by isolation regions. The method further includes replacing the dummy gates with metal gate stacks and gate caps, then, after formation of a dielectric layer (e.g., ILD oxide) and planarizing the structure, forming a cap layer over the planarized structure, and then forming trenches (for contacts), for example, by a litho/etching process, through the cap layer to expose source regions and drain regions of the transistors, allowing for self-aligned source and drain contacts with respect to the metal gate stacks.

In one example, the starting semiconductor structure in the method of the first aspect may include, for example, a top blanket layer of low-k dielectric, and the method may further include, for example, selectively removing horizontal portions of the top blanket layer of low-k dielectric, leaving the remaining low-k dielectric (e.g., CESL) to act as spacer.

In one example, the method of the first aspect may further include, for example, forming a low-k dielectric layer on the isolation regions and along adjacent source and drain sidewalls prior to forming the cap.

In one example, the starting semiconductor structure in the method of the first aspect may further include, for example, a blanket conformal dielectric layer over the structure, and the method may further include, for example, planarizing the structure prior to replacing the dummy gates.

In a second aspect, disclosed above is a semiconductor structure. The semiconductor structure includes a semiconductor substrate, transistors electrically isolated by isolation regions, each transistor having a metal gate with gate cap and spacers, a source and a drain. The structure further includes protective layer(s) on the isolation regions and along adjacent source and drain sidewalls, and a blanket cap layer over the semiconductor structure with trenches therein exposing the sources and drains.

In one example, the cap layer may include, for example, a bottom blanket cap layer, and a top blanket conformal layer over the bottom blanket cap layer.

In one example, the protective layer(s) in the semiconductor structure of the second aspect may include, for example, a contact etch stop layer.

In one example, the protective layer in the semiconductor structure of the second aspect may include, for example, a low-k dielectric layer. In one example, the semiconductor structure with a low-k dielectric layer may lack, for example, a contact etch stop layer.

In one example, the protective layer(s) may include, for example, a contact etch stop layer on the source and drain sidewalls, and a capping layer on the isolation regions.

In a third aspect, disclosed above is a semiconductor structure. The semiconductor structure includes a semiconductor substrate, transistors electrically isolated by isolation regions, each transistor having a dummy gate with gate cap and spacers, a source and a drain. The structure further includes a protective layer only on vertical sidewalls of the sources, drains and spacers.

In one example, the protective layer of the third aspect may include, for example, a contact etch stop layer.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method, comprising:
providing a starting semiconductor structure, the starting semiconductor structure comprising a semiconductor substrate, a plurality of transistors in process having dummy gates and electrically isolated by isolation regions;
replacing the dummy gates with metal gate stacks and gate caps;
planarizing the structure after the replacing;
forming a cap over the planarized structure; and
forming trenches through the cap to expose source regions and drain regions of the plurality of transistors, allowing for self-aligned source and drain contacts with respect to the metal gate stacks.

2. The method of claim 1, wherein forming the cap comprises:
forming a first blanket cap layer over the structure with metal gates; and
forming a second blanket cap layer over the first blanket cap layer.

3. The method of claim 1, wherein the starting semiconductor structure comprises a top blanket layer of low-k dielectric, the method further comprising selectively removing horizontal portions of the top blanket layer of low-k dielectric, remaining portions of the low-k dielectric acting as spacers.

4. The method of claim 1, further comprising forming a low-k dielectric layer on the isolation regions and along adjacent source and drain sidewalls prior to forming the cap.

5. The method of claim 1, wherein the starting semiconductor structure further comprises a blanket conformal dielectric layer over the structure, the method further comprising planarizing the structure prior to replacing the dummy gates.

6. A semiconductor structure, comprising:
a semiconductor substrate;
a plurality of transistors electrically isolated by isolation regions, each transistor having a metal gate with gate cap and spacers, a source and a drain;
one or more protective layers on the isolation regions and along adjacent source and drain sidewalls; and
a blanket cap layer over the semiconductor structure with trenches therein exposing the sources and drains.

7. The semiconductor structure of claim 6, wherein the cap layer comprises:
a bottom blanket cap layer; and
a top blanket conformal layer over the bottom blanket cap layer.

8. The semiconductor structure of claim 6, wherein the one or more protective layers comprise a contact etch stop layer.

9. The semiconductor structure of claim 6, wherein the protective layer comprises a low-k dielectric layer.

10. The semiconductor structure of claim 9, wherein the semiconductor structure lacks a contact etch stop layer.

11. The semiconductor structure of claim 6, wherein the one or more protective layers comprise:
a contact etch stop layer on the source and drain sidewalls; and
a capping layer on the isolation regions.

12. A semiconductor structure, comprising:
a semiconductor substrate;
a plurality of transistors electrically isolated by isolation regions, each transistor having a dummy gate with gate cap and spacers, a source and a drain; and
a protective layer only on vertical sidewalls of the sources, drains and spacers.

13. The semiconductor structure of claim 12, wherein the protective layer comprises a contact etch stop layer.
